(19) United States
(12) Patent Application Publication
(10) Pub. No.: US 2018/0299494 A1
(43) Pub. Date: Oct. 18, 2018

(54) HAND TOOL STRUCTURE

(71) Applicant: Chao-Chin YEN, New Taipei City (TW)

(72) Inventor: Chao-Chin YEN, New Taipei City (TW)

(21) Appl. No.: 15/487,715

(22) Filed: Apr. 14, 2017

(51) Int. Cl. G01R 19/15; H02G 1/12

(52) U.S. Cl. CPC G01R 19/15; H02G 1/1214

(57) ABSTRACT

A hand tool structure (10) includes a housing (1), a wire stripper assembly (2), a circuit board (3), a current sensor (4), and one or more alert units (5). The housing (1) includes an opening (14). The wire stripper assembly (2) is accommodated in the housing (1) and is disposed corresponding to the opening (14). The circuit board (3) is disposed in the housing (1). The circuit board (3) includes a controller (31). The current sensor (4) is electrically connected to the circuit board (3) and is disposed adjacent to the wire stripper assembly (2). The current sensor (4) senses current and generates an electrical signal. The alert unit (5) is electrically connected to the circuit board (3). After receiving the electrical signal, the controller (31) controls the alert unit (5) to send out an alert.

### TECHNICAL FIELD

The present invention relates to a hand tool for stripping an electrical insulation layer from wires and for cutting wires and, in particular, to a hand tool structure.

### BACKGROUND

In maintenance and arrangement of electrical wiring or plumbing, it is often required to remove an electrical insulation layer from wires, so that a wire core in the wire can be exposed to facilitate subsequent electrical connection operations. As a result, there is a wire stripper in the market, used to remove the electrical insulation layer from the wire without damaging the wire core inside the wire, thus wire stripping can be carried out smoothly.

However, it is unable to judge whether the wire is carrying current with bare eyes. The wire stripper is made from metal. Therefore, when an operator uses a wire stripper to cut or clamp wires, incidents like electric shocks, short-circuits and electric fires tend to occur if the wire is carrying current. Thus, industries aim to enhance safety in use of the wire strippers.

In views of this, in order to solve the above disadvantage, the present inventor studied related technology and provided a reasonable and effective solution in the present disclosure.

### SUMMARY

The present invention provides a hand tool structure, wherein when a current sensor senses a current, an alert unit sends out an alert to remind an operator, thus preventing incidents like electric shocks, short-circuits, and electric fires, thereby enhancing safety in use of the hand tool structure.

The present invention provides a hand tool structure, comprising: a housing including a first cover and a second cover, the first cover and the second cover each having on one lateral edge a pivot portion for pivotally connected with each other, an opening being formed on respective another lateral edges of the first cover and the second cover; a wire stripper assembly accommodated between the first cover and the second cover and disposed corresponding to the opening; a circuit board disposed between the first cover and the second cover, the circuit board including a controller; a current sensor electrically connected to the circuit board and disposed adjacent to the wire stripper assembly, the current sensor sensing current and generating an electrical signal; and at least one alert unit electrically connected to the circuit board, wherein after receiving the electrical signal, the controller controls the alert unit to send out an alert.

### BRIEF DESCRIPTION OF THE DRAWINGS

The disclosure will become more fully understood from the detailed description and the drawings given herein below for illustration only, and thus does not limit the disclosure, wherein:

FIG. 1 is a perspective assembled view showing a hand tool structure according to the present invention;

FIG. 2 is a perspective exploded view showing the hand tool structure according to the present invention;

FIG. 3 is another perspective exploded view showing the hand tool structure according to the present invention; and

FIG. 4 is a schematic view illustrating the hand tool structure in use.

### DETAILED DESCRIPTION

Detailed descriptions and technical contents of the present invention are illustrated below in conjunction with the accompany drawings. However, it is to be understood that the descriptions and the accompany drawings disclosed herein are merely illustrative and exemplary and not intended to limit the scope of the present invention.

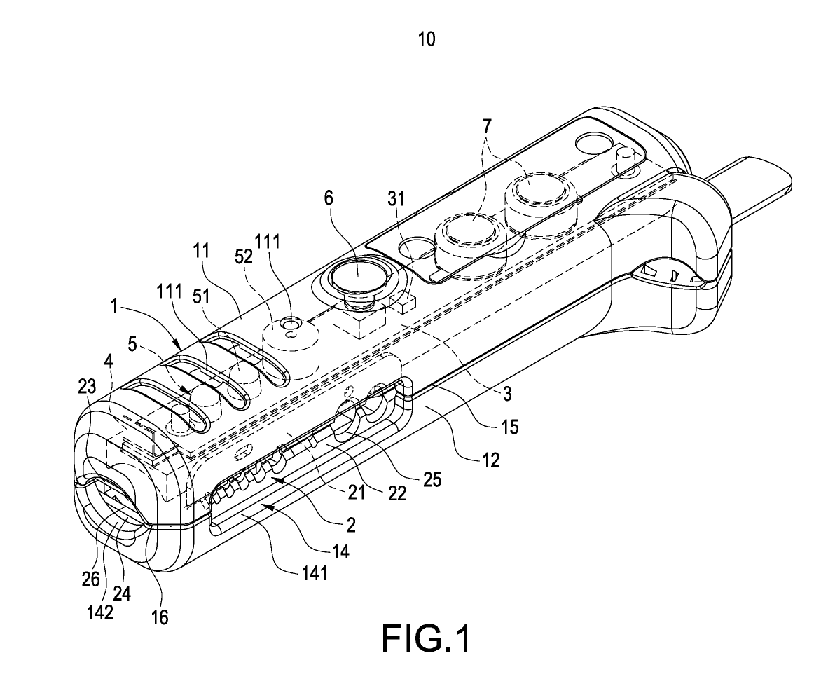

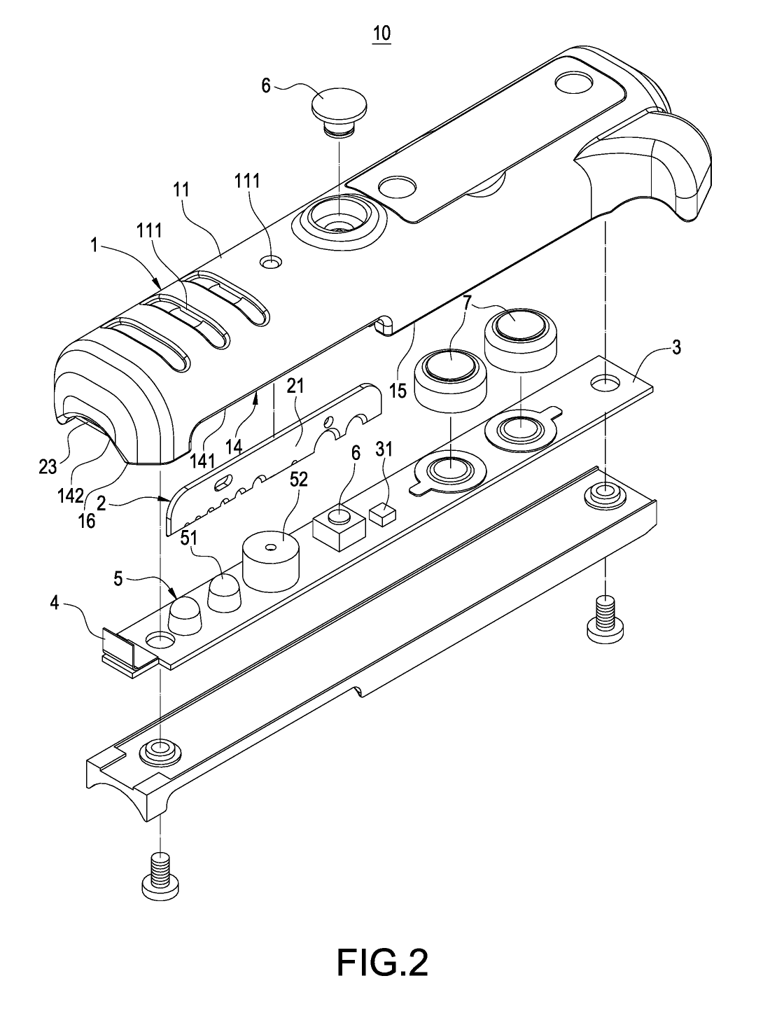

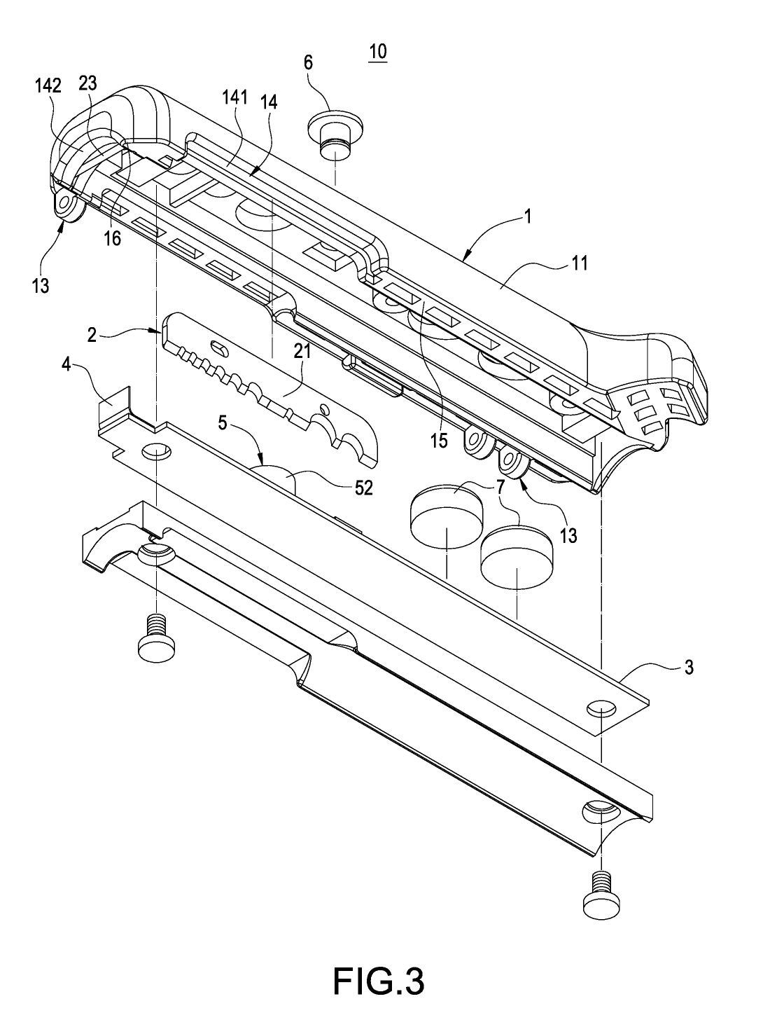

Referring to FIGS. 1 to 4, the present invention provides a hand tool structure. The hand tool structure 10 includes a housing 1, a wire stripper assembly 2, a circuit board 3, a current sensor 4, and one or multiple alert units 5.

The housing 1 includes a first cover 11 and a second cover 12. The first cover 11 and the second cover 12 each have, on one lateral edge thereof, a pivot portion 13 for pivotally connected with each other, so that the first cover 11 and the second cover 12 pivot about the pivot portion 13 to be opened or closed. An opening 14 is formed on respective another lateral edges of the first cover 11 and the second cover 12. The opening 14 includes a first opening 141 and a second opening 142. The first cover 11 and the second cover 12 each include a front end 15 disposed opposite to the pivot portion 13 and each also include two side ends 16 disposed at two sides of the front end 15, the first opening 141 is formed on the front end 15, the second opening 142 is formed on one of the side ends 16, and the first cover 11 includes one or multiple through holes 111.

The wire stripper assembly 2 is accommodated between the first cover 11 and the second cover 12 and is disposed corresponding to the opening 14. The wire stripper assembly 2 includes a first wire stripping blade 21, a second wire stripping blade 22, a first cut-off blade 23, and a second cut-off blade 24, the first wire stripping blade 21 and the first cut-off blade 23 are fixed inside the first cover 11 and move along with the first cover 11, the second wire stripping blade 22 and the second cut-off blade 24 are fixed inside the second cover 12 and move along with the second cover 12, the first wire stripping blade 21 and the second wire stripping blade 22 are disposed corresponding to the opening 14 and together form a wire stripping opening 25, the wire stripping opening 25 is disposed corresponding to the first opening 141, the first cut-off blade 23 and the second cut-off blade 24 are disposed corresponding to the opening 14 and together form a cut-off opening 26, and the cut-off opening 26 is disposed corresponding to the second opening 142.

The circuit board 3 is disposed between the first cover 11 and the second cover 12, and the circuit board 3 includes a controller 31. According to the present embodiment, the circuit board 3 is fixed by a screw or other fastening element inside the first cover 11. However, the present invention is not limited in this regard. The circuit board 3 can be fixed inside the second cover 12 instead, by a screw or other fastening elements.

The current sensor 4 is electrically connected to the circuit board 3 and is disposed adjacent to the wire stripper assembly 2, and the current sensor 4 is used to sense current and generate an electrical signal.

In detail, the current sensor 4 can be arranged in two different ways. First, if the current sensor 4 senses the current by electrical conduction, the current sensor 4 is in electrical contact with the wire stripper assembly 2. Second, if the current sensor 4 senses the current by an electromagnet effect, the current sensor 4 is not required to make electrical contact with the wire stripper assembly 2, and the current sensor 4 needs only to be disposed adjacent to the wire stripper assembly 2.

The alert unit 5 is electrically connected to the circuit board 3. After receiving the electrical signal, the controller 31 controls the alert unit 5 to send out an alert. The alert unit 5 can be a lamp 51, a buzzer 52, or a display panel. The through holes 111 are provided corresponding in number to the number of the alert units 5. The alert unit 5 is exposed from the first cover 11 via the through hole 111.

Furthermore, the alert unit 5 can function according to, but not limited to, the following example ways. When the alert unit 5 is the lamp 51, the lamp 51 emits red light as an alert which indicates that the current sensor 4 senses current. When the alert unit 5 is a buzzer 52, the buzzer 52 emits a sound to indicate that the current sensor 4 senses current. When the alert unit 5 is a display panel, it displays words “power is on” to indicate that the current sensor 4 senses the current.

The hand tool structure 10 further comprises a switch element 6, the switch element 6 is assembled to the first cover 11 and is electrically connected to the circuit board 3, the switch element 6 controls the circuit board 3 to be electrically connected to or disconnected from the current sensor 4, and the switch element 6 is a press type switch or a touch switch.

The hand tool structure 10 comprises a battery 7. According to the present embodiment, the battery 7 is installed in the first cover 11; however, the present invention is not limited in this regard. The battery 7 can be installed in one of the first cover 11 and the second cover 12, and the battery 7 is electrically connected to the circuit board 3. The battery 7 supplies power to the current sensor 4, the alert unit 5 and the switch element 6.

In the hand tool structure 10 of the present invention, the housing 1 includes a first cover 11 and a second cover 12. The first cover 11 and the second cover 12 each have, on one lateral edge thereof, a pivot portion 13 for pivotally connected with each other, an opening 14 is formed on respective another lateral edges of the first cover 11 and the second cover 12. The wire stripper assembly 2 is accommodated between the first cover 11 and the second cover 12 and is disposed corresponding to the opening 14. The circuit board 3 is disposed between the first cover 11 and the second cover 12. The circuit board 3 includes a controller 31. The current sensor 4 is electrically connected to the circuit board 3 and is disposed adjacent to the wire stripper assembly 2. The current sensor 4 is used to sense current and generate the electrical signal. The alert unit 5 is electrically connected to the circuit board 3. After receiving the electrical signal, the controller 31 controls the alert unit 5 to send out the alert.

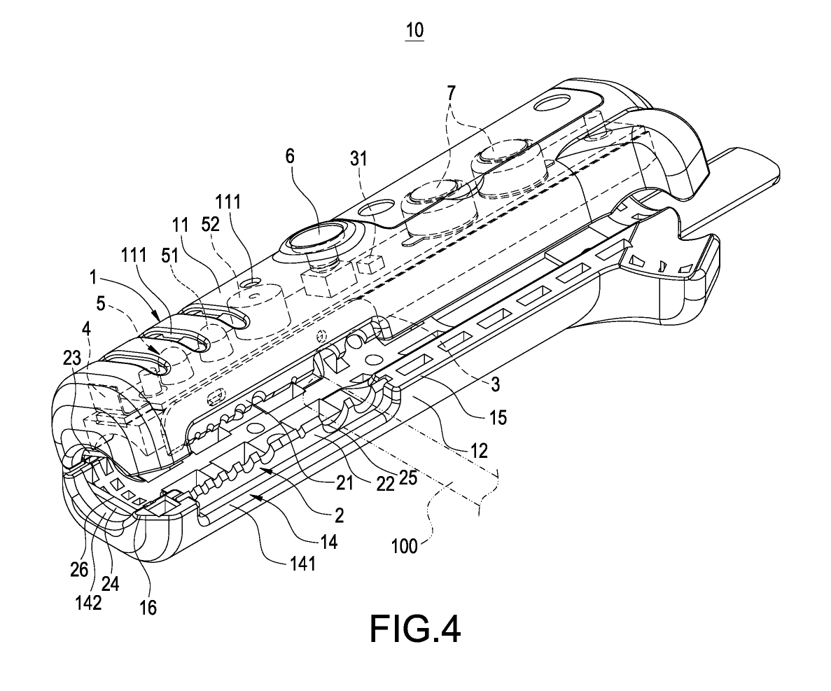

Referring to FIG. 4 showing the hand tool structure 10 in use, when performing stripping or cutting operations on a wire 100, the current sensor 4 can sense whether the wire 100 is carrying current. If the wire 100 is carrying current, the alert unit 5 sends out the alert to remind an operator, thus preventing electric shocks, short-circuits and electric fires, thereby enhancing safety in use of the hand tool structure 10.

Moreover, the wire stripper assembly 2 of the hand tool structure 10 is accommodated between the first cover 11 and the second cover 12, the first cover 11 and the second cover 12 are pivotally connected to each other, and opening and closing of the first cover 11 and the second cover 12 drives movement of the wire stripper assembly 12, so that it is easy and convenient to carry the hand tool structure 10 around, less force is required for operations, and the hand tool structure 10 can be operated easily and conveniently.

Furthermore, the first cover 11 and the second cover 12 form an opening 14 at their lateral edges, so that an insulation layer of unlimited length may be stripped from the wire 100. In other words, the wire stripper assembly 12 has a large work area.

In summary, the hand tool structure certainly can achieve anticipated objectives and solve the conventional defects. The present invention also has industrial applicability, novelty and non-obviousness, so the present invention completely complies with the requirements of patentability. Therefore, a request to patent the present invention is filed pursuant to patent law. Examination is kindly requested, and allowance of the present application is solicited to protect the rights of the inventor.

What is claimed is:

1. A hand tool structure, comprising:
a housing (1) including a first cover (11) and a second cover (12), each of the first cover (11) and the second cover (12) having on one lateral edge a pivot portion (13) for pivotally connected with each other, an opening (14) being formed on respective another lateral edges of the first cover (11) and the second cover (12);
a wire stripper assembly (2) accommodated between the first cover (11) and the second cover (12) and disposed corresponding to the opening (14);
a circuit board (3) disposed between the first cover (11) and the second cover (12), the circuit board (3) including a controller (31);
a current sensor (4) electrically connected to the circuit board (3) and disposed adjacent to the wire stripper assembly (2), the current sensor (4) sensing current and generating an electrical signal; and
at least one alert unit (5) electrically connected to the circuit board (3), wherein after receiving the electrical signal, the controller (31) controls the alert unit (5) to send out an alert.

2. The hand tool structure of claim 1, wherein the wire stripper assembly (2) includes a first wire stripping blade (21), a second wire stripping blade (22), a first cut-off blade (23), and a second cut-off blade (24), the first wire stripping blade (21) and the first cut-off blade (23) are fixed inside the first cover (11) and move along with the first cover (11), the second wire stripping blade (22) and the second cut-off blade (24) are fixed inside the second cover (12) and move along with the second cover (12), the first wire stripping blade (21) and the second wire stripping blade (22) are disposed corresponding to the opening (14) and together form a wire stripping opening (25), and the first cut-off blade (23) and the second cut-off blade (24) are disposed corresponding to the opening (14) and together form a cut-off opening (26).

3. The hand tool structure of claim 2, wherein the opening (14) includes a first opening (141) and a second opening (142), the first cover (11) and the second cover (12) each include a front end (15) disposed opposite to the pivot portion (13) and each also include two side ends (16) disposed at two sides of the front end (15), the first opening (141) is formed on the front end (15), the wire stripping opening (25) is disposed corresponding to the first opening (141), the second opening (142) is formed on one of the side ends (16), and the cut-off opening (26) is disposed corresponding to the second opening (142).

4. The hand tool structure of claim 1, wherein the first cover (11) includes at least one through hole (111), and the alert unit (5) is exposed from the first cover (11) via the through hole (111).

5. The hand tool structure of claim 4, wherein the alert unit (5) is a lamp (51), a buzzer (52), or a display panel.

6. The hand tool structure of claim 1, further comprising a switch element (6), the switch element (6) being assembled to the first cover (11) and electrically connected to the circuit board (3), the switch element (6) controlling the circuit board (3) to be electrically connected to or disconnected from the current sensor (4), the switch element (6) being a press type switch or a touch switch.

7. The hand tool structure of claim 1, wherein the circuit board (3) is fixed inside the first cover (11) or the second cover (12).

8. The hand tool structure of claim 1, further comprising a battery (7), the battery (7) being installed in one of the first cover (11) and the second cover (12), the battery (7) being electrically connected to the circuit board (3).

9. The hand tool structure of claim 1, wherein the current sensor (4) is in electrical contact with the wire stripper assembly (2), and the current sensor (4) senses the current by electrical conduction.

10. The hand tool structure of claim 1, wherein the current sensor (4) makes no electrical contact with the wire stripper assembly (2), and the current sensor (4) senses the current by an electromagnet effect.
